(19) United States
(12) Patent Application Publication
(10) Pub. No.: US 2024/0141533 A1
(43) Pub. Date: May 2, 2024

(54) MASKING MATERIAL, AND FILM FORMING APPARATUS AND FILM FORMING METHOD FOR FORMING METAL FILM USING SAME

(71) Applicant: TOYOTA JIDOSHA KABUSHIKI KAISHA, Toyota-shi (JP)

(72) Inventors: Haruki KONDOH, Okazaki-shi (JP); Koji INAGAKI, Toyota-shi (JP); Keiji KURODA, Toyota-shi (JP); Soma HIGASHIKOZONO, Toyota-shi (JP)

(73) Assignee: TOYOTA JIDOSHA KABUSHIKI KAISHA, Toyota-shi (JP)

(21) Appl. No.: 18/488,155

(22) Filed: Oct. 17, 2023

(30) Foreign Application Priority Data
Oct. 26, 2022 (JP) 2022-171622
Jul. 6, 2023 (JP) 2023-111203

(51) Int. Cl. C25D 5/02; C25D 5/04

(52) U.S. Cl. CPC C25D 5/022; C25D 5/04

(57) ABSTRACT

The masking material includes a penetrating portion according to a predetermined pattern. The masking material includes a mask portion and at least the mask portion contacting the substrate is made of an elastic material. The penetrating portion includes an expanded portion that is expanded outwardly from a portion contacting the substrate toward the electrolyte membrane in a thickness direction of the mask portion such that in a state where the mask portion is elastically deformed by a pressing force of the electrolyte membrane, a shape of a cross section of a formation space of the penetrating portion in which the metal film is to be formed becomes rectangular.

### CROSS REFERENCE TO RELATED APPLICATIONS

The present application claims priority from Japanese patent application JP 2022-171622 filed on Oct. 26, 2022 and Japanese patent application JP 2023-111203 filed on Jul. 6, 2023, the entire content of which is hereby incorporated by reference into this application.

### BACKGROUND

### Technical Field

The present disclosure relates to a masking material, and a film forming apparatus and film forming method for forming a metal film using the same.

### Background Art

Conventionally, a metal film is formed by depositing metal on the surface of a substrate by electroplating (for example, JP 2016-125087 A). The film forming apparatus disclosed in JP 2016-125087 A includes a housing containing a plating solution. The housing has an opening that is sealed with an electrolyte membrane. The film forming apparatus further includes a pressing mechanism that presses the electrolyte membrane against the substrate with a fluid pressure of the plating solution.

Here, when a metallic underlayer having a predetermined pattern on the surface of the substrate is formed, the film forming apparatus applies a voltage between the anode and the substrate while pressing the substrate with the fluid pressure of the electrolyte membrane. Thus, the film forming apparatus can form a metal film having the predetermined pattern on the underlayer. However, when an underlayer having a predetermined pattern is not formed on the substrate, it is also conceivable to use, for example, a masking material disclosed in JP 2016-108586 A.

### SUMMARY

Here, when a metal film is formed, the masking material is sandwiched between the substrate and the electrolyte membrane. In this state, in order to ensure the adhesion between the substrate and the masking material, the masking material is pressed by the electrolyte membrane on which the fluid pressure of the plating solution is acting. However, using an elastic material for the masking material to ensure the adhesion of the masking material may cause compression and deformation of the masking material, and a metal film having a rectangular cross section may not be formed.

The present disclosure has been made in view of the foregoing, and provides a masking material capable of forming a metal film having a rectangular cross section.

In view of the foregoing, a masking material according to the present disclosure is a masking material for forming a metal film having a predetermined pattern on a surface of a substrate by electroplating in a state where the masking material is pressed by an electrolyte membrane. The masking material includes a penetrating portion according to the predetermined pattern. The masking material includes a mask portion and at least the mask portion contacting the substrate is made of an elastic material. The penetrating portion includes an expanded portion that is expanded outwardly from a portion contacting the substrate toward the electrolyte membrane in a thickness direction of the mask portion such that in a state where the mask portion is elastically deformed by a pressing force of the electrolyte membrane, a shape of a cross section of a formation space of the penetrating portion in which the metal film is to be formed becomes rectangular.

According to the present disclosure, since the mask portion is made of an elastic material, the mask portion elastically deforms when the electrolyte membrane is pressed against the substrate via the masking material with the fluid pressure of the plating solution contacting the electrolyte membrane. At this time, since the mask portion elastically deforms such that the expansion of the expanded portion of the penetrating portion narrows, the shape of the cross section of the formation space of the penetrating portion in which the metal film is to be formed becomes rectangular. By forming a metal film on the surface of the substrate using such an elastically deformed masking material, the metal film can be formed to have a rectangular cross section.

Here, the shape of the penetrating portion of the masking material is not particularly limited as long as the penetrating portion is elastically deformed into a rectangular shape by a pressing force of the electrolyte membrane. However, in some embodiments, the expanded portion of the penetrating portion is a space formed to be expanded from a portion contacting the substrate and from a portion contacting the electrolyte membrane toward an interior of the mask portion in the thickness direction of he mask portion. Specifically, a side wall surface forming the expanded portion is a concave curved surface bent along the thickness direction.

According to this embodiment, when the electrolyte membrane is pressed against the substrate via the masking material, the mask portion elastically deforms. During film formation, the surface of a portion of the mask portion contacting the substrate is in close contact with and tied to the substrate, and the surface of a portion of the mask portion contacting the electrolyte membrane is in close contact with and tied to the electrolyte membrane. Consequently, the mask portion deforms along the thickness direction as a whole by the pressing force of the electrolyte membrane. Thus, the mask portion tends to deform such that the wall surface forming the penetrating portion intersects the surface of the substrate. Consequently, the overall shape of the cross section of the formation space of the penetrating portion in which the metal film is to be formed tends to be deformed into a more precise rectangular shape. In particular, since the side wall surface forming the expanded portion is a concave curved surface bent along the thickness direction, the penetrating portion can be deformed into a more precise rectangular shape.

In some embodiments, the expanded portion of the penetrating portion is a space formed to be expanded from a portion contacting the substrate to a portion contacting the electrolyte membrane across the mask portion in the thickness direction.

According to this embodiment, when the electrolyte membrane is pressed against the substrate via the masking material, the mask portion elastically deforms. During film formation, the surface of a portion of the mask portion contacting the substrate is in close contact with and tied to the substrate, and the surface of a portion of the mask portion contacting the electrolyte membrane is in close contact with and tied to the electrolyte membrane. Consequently, the region around the portion contacting the substrate deforms by the pressing force of the electrolyte membrane. Thus, the mask portion tends to deform such that the wall surface forming the penetrating portion intersects the surface of the substrate. Consequently, the shape of the cross section of the formation space of the penetrating portion in which the metal film is to be formed tends to be deformed into a rectangular shape. In particular, since the side wall surface forming the expanded portion is a concave curved surface bent along the thickness direction, the formation space can be deformed into a more precise rectangular shape.

In some embodiments, the masking material includes a mesh portion including a plurality of openings in a grid pattern, and the mask portion is securely attached to the mesh portion.

According to this embodiment, since the mask portion is securely attached to the mesh portion, the mask portion can be uniformly pressed via the mesh portion. This allows the mask portion to elastically deform uniformly by the pressing force of the electrolyte membrane.

The present disclosure relates to a film forming apparatus for forming a metal film, provided with the above-stated masking material. A film forming apparatus according to the present disclosure includes: a housing having an opening at a position facing the substrate, the opening being covered with the electrolyte membrane while the housing contains a plating solution; a moving mechanism configured to move at least one of the housing or the substrate to allow the electrolyte membrane and the substrate to be brought into contact with and separated from each other via the masking material; a booster mechanism configured to increase a fluid pressure of the plating solution contained in the housing; an anode disposed inside of the housing at a position facing the electrolyte membrane; a power supply configured to apply a voltage between the anode and the substrate; and the masking material placed between the electrolyte membrane and the substrate.

According to the present disclosure, the moving mechanism causes the electrolyte membrane and the substrate to contact each other via the masking material. In this state, the booster mechanism presses the electrolyte membrane against the substrate via the masking material with a fluid pressure of the plating solution contacting the electrolyte membrane. This allows the mask portion to elastically deform, and allows the shape of the cross section of the formation space of the penetrating portion in which the metal film is formed to be deformed into a rectangular shape. Also, the plating solution contained in the housing is exuded from the electrolyte membrane and filled into the penetrating portion. When the power supply applies a voltage between the anode and the substrate in this state, metal ions contained in the plating solution are allowed to pass through the electrolyte membrane, and a metal film derived from the metal ions can be formed on the substrate in a predetermined pattern. The shape of the cross section of the formed metal film is rectangular according to the shape of the cross section of the penetrating portion.

The present disclosure relates to a film forming method for forming a metal film using the above-stated masking material. A film forming method according to the present disclosure includes; covering a substrate with the masking material; pressing an electrolyte membrane against the substrate via the masking material with a fluid pressure of a plating solution contacting the electrolyte membrane; and applying a voltage between an anode contacting the plating solution and the substrate to allow metal ions contained in the plating solution to pass through the electrolyte membrane and form a metal film derived from the metal ions on the substrate in the predetermined pattern.

According to the present disclosure, the substrate is covered with the masking material, and the electrolyte membrane is pressed against the substrate via the masking material with a fluid pressure of a plating solution contacting the electrolyte membrane. This allows the mask portion to elastically deform, and allows the shape of the cross section of the formation space of the penetrating portion in which the metal film is formed to be deformed into a rectangular shape. Also, the plating solution contained in the housing is exuded from the electrolyte membrane and filled into the penetrating portion. When a voltage is applied between the anode and the substrate in this state, metal ions contained in the plating solution are allowed to pass through the electrolyte membrane, and a metal film derived from the metal ions can be formed on the substrate in a predetermined pattern. The shape of the cross section of the formed metal film is rectangular according to the shape of the cross section of the penetrating portion.

According to the present disclosure, it is possible to form a metal film having a rectangular cross section.

### BRIEF DESCRIPTION OF THE DRAWINGS

FIG. 1 is a schematic cross-sectional view illustrating an example of a film forming apparatus for forming a metal film according to a first embodiment of the present disclosure;

FIG. 2 is a schematic perspective view of a masking material shown in FIG. 1 and a substrate on which a metal film is formed;

FIG. 3 is an enlarged cross-sectional view taken along line A-A shown in FIG. 2 for explaining the masking material using the film forming apparatus shown in FIG. 1;

FIG. 4A is a schematic cross-sectional view for explaining a method of manufacturing the masking material shown in FIG. 2;

FIG. 4B is a schematic cross-sectional view for explaining the method of manufacturing the masking material shown in FIG. 2;

FIG. 4C is a schematic cross-sectional view for explaining the method of manufacturing the masking material shown in FIG. 2;

FIG. 4D is a schematic cross-sectional view for explaining the method of manufacturing the masking material shown in FIG. 2;

FIG. 5 is a schematic cross-sectional view for explaining film formation by the film forming apparatus shown in FIG. 1;

FIG. 6A is a schematic view for explaining a placing step using the masking material according to the first embodiment;

FIG. 6B is a schematic view for explaining a pressing step using the masking material according to the first embodiment;

FIG. 6C is a schematic view for explaining a film forming step using the masking material according to the first embodiment;

FIG. 7A is a schematic view for explaining a placing step using a masking material according to a second embodiment;

FIG. 7B is a schematic view for explaining a pressing step using the masking material according to the second embodiment;

FIG. 7C is a schematic view for explaining a film forming step using the masking material according to the second embodiment;

FIG. 8A is a schematic cross-sectional view for explaining a method of manufacturing the masking material shown in FIG. 7A;

FIG. 8B is a schematic cross-sectional view for explaining the method of manufacturing the masking material shown in FIG. 7A;

FIG. 8C is a schematic cross-sectional view for explaining the method of manufacturing the masking material shown in FIG. 7A;

FIG. 8D is a schematic cross-sectional view for explaining the method of manufacturing the masking material shown in FIG. 7A;

FIG. 8E is a schematic cross-sectional view for explaining the method of manufacturing the masking material shown in FIG. 7A;

FIG. 8F is a schematic cross-sectional view for explaining the method of manufacturing the masking material shown in FIG. 7A;

FIG. 9A is a schematic view for explaining a placing step using a masking material according to a third embodiment;

FIG. 9B is a schematic view for explaining a pressing step using the masking material according to the third embodiment; and

FIG. 9C is a schematic view for explaining a film forming step using the masking material according to the third embodiment.

### DETAILED DESCRIPTION

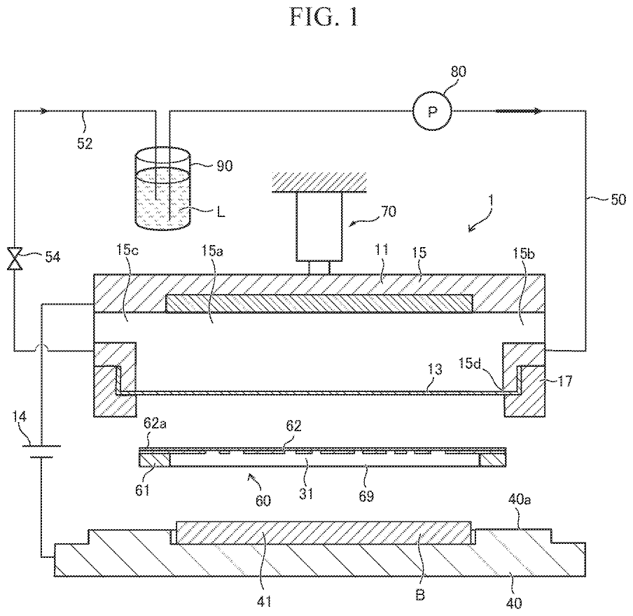

First, a film forming apparatus 1 used for a film forming method for forming a metal film according to an embodiment of the present disclosure will be described. FIG. 1 is a schematic cross-sectional view illustrating an example of the film forming apparatus for forming a metal film according to the first embodiment of the present disclosure.

As shown in FIG. 1, the film forming apparatus 1 is a film forming apparatus for forming a metal film F having a predetermined pattern P on a substrate B by electroplating in a state where a masking material 60 is sandwiched between an electrolyte membrane 13 and the substrate B. Specifically, the film forming apparatus 1 includes an anode 11, the electrolyte membrane 13, and a power supply 14 that applies a voltage between the anode 11 and the substrate B.

The film forming apparatus 1 includes a housing 15 containing the anode 11 and a plating solution L, a mount base 40 on which the substrate B is to be placed, and the masking material 60. At the time of film formation, the masking material 60 is placed on the mount base 40 together with the substrate B. The electrolyte membrane 13 is disposed between the masking material 60 and the anode 11.

The film forming apparatus 1 includes a linear actuator 70 for raising and lowering the housing 15. The linear actuator 70 corresponds to a “moving mechanism” of the present disclosure and may be any device configured to move at least one of the housing 15 or the substrate B to allow the electrolyte membrane 13 and the substrate B to be brought into contact with and separated from each other via the masking material 60 (described later). Thus, the linear actuator 70 may be provided on the mount base 40. In the present embodiment, for convenience of explanation, the electrolyte membrane 13 is disposed below the anode 11, and the masking material 60 and the substrate B are disposed below the electrolyte membrane 13. However, the positional relation is not limited to this as long as the metal film F can be formed on the surface of the substrate B.

The substrate B functions as a cathode. The substrate B is a plate-shaped substrate. In the present embodiment, the substrate B is a rectangular substrate. One of the surfaces of the substrate B faces the electrolyte membrane 13 (a screen mask 62), and this surface serves as a film forming surface that functions as a cathode. The material of the substrate B is not particularly limited as long as the substrate B functions as a cathode (i.e., a conductive surface). Examples of the material of the substrate B may include a metal material such as aluminum or copper.

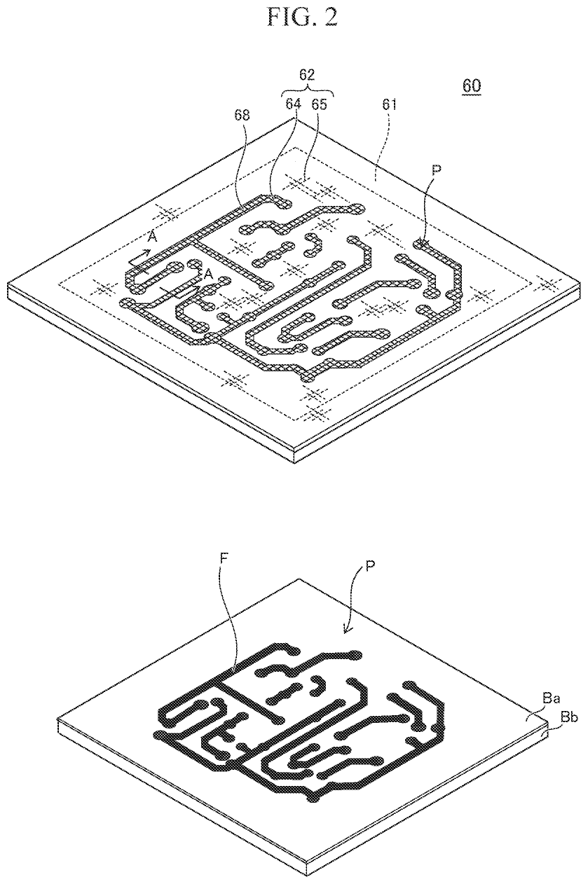

In the present embodiment, as shown in FIG. 2, since a wiring pattern is formed using the metal film F, for the substrate B, a substrate having an underlayer Bb of copper or the like formed on the surface of an insulating substrate Ba made of a resin or the like may be used. In this case, after the metal film F is formed, the underlayer Bb other than the portion on which the metal film F is formed is removed by etching or the like. In this way, a pattern (a wiring pattern) P using the metal film F can be formed on the surface of the insulating substrate Ba.

In one example, the anode 11 is a non-porous (e.g., poreless) anode made of the same metal as the metal of the metal film. The anode 11 has a block shape or a flat plate shape. Examples of the material of the anode 11 may include copper or the like. The anode 11 dissolves when a voltage is applied by the power supply 14. However, when a film is formed using only metal ions of the plating solution L, the anode 11 is an anode insoluble in the plating solution L. The anode 11 is electrically connected to the positive electrode of the power supply 14. The negative electrode of the power supply 14 is electrically connected to the substrate B via the mount base 40.

The plating solution L is a liquid containing the metal of the metal film to be formed in the state of ions. Examples of the metal may include copper, nickel, gold, silver, iron, or the like. The plating solution L is a solution obtained by dissolving (ionizing) these metals in an acid such as nitric acid, phosphoric acid, succinic acid, sulfuric acid, or pyrophosphoric acid. Examples of the solvent of the solution may include water and alcohol. For example, when the metal is copper, examples of the plating solution L may include an aqueous solution containing copper sulfate, copper pyrophosphate, or the like.

The electrolyte membrane 13 is a membrane that is able to be impregnated with metal ions (i.e., contain metal ions therein) together with the plating solution L by being brought into contact with the plating solution L. The electrolyte membrane 13 is a flexible membrane. The material of the electrolyte membrane 13 is not particularly limited as long as metal ions of the plating solution L can move toward the substrate B when the power supply 14 applies a voltage. Examples of the material of the electrolyte membrane 13 may include a resin having an ion-exchange function such as a fluorine-based resin such as Nafion (registered trademark) available from DuPont. The film thickness of the electrolyte membrane 13 may be in the range of 20 μm to 200 μm. Specifically, the film thickness may be in the range of 20 μm to 60 μm.

The housing 15 is made of a material insoluble in the plating solution L. The housing 15 includes a storage space 15a for storing the plating solution L. The anode 11 is disposed in the storage space 15a of the housing 15. The storage space 15a includes an opening 15d on the side adjacent to the substrate B. The opening 15d of the housing 15 is covered with the electrolyte membrane 13. Specifically, the peripheral edge of the electrolyte membrane 13 is sandwiched between the housing 15 and a frame 17. Accordingly, the plating solution L in the storage space 15a can be sealed with the electrolyte membrane 13.

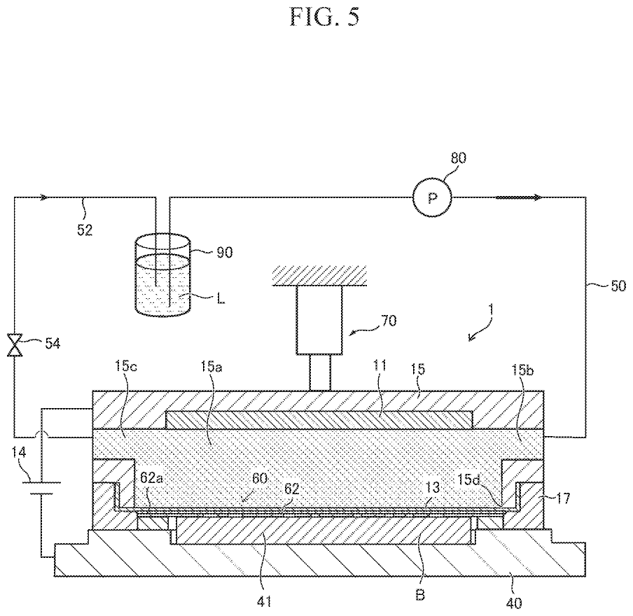

As shown in FIG. 1 and FIG. 5, the linear actuator 70 raises and lowers the housing 15 such that the electrolyte membrane 13 and the masking material 60 can be brought into contact with and separated from each other. In the present embodiment, the mount base 40 is fixed, and the housing 15 is moved up and down by the linear actuator 70. The linear actuator 70 is an electric actuator, and converts the rotational motion of the motor into a linear motion by a ball screw or the like (not shown). However, instead of an electric actuator, a hydraulic or pneumatic actuator may be used.

The housing 15 includes a supply port 15b for supplying the plating solution L to the storage space 15a. Further, the housing 15 includes a discharge port 15c for discharging the plating solution L from the storage space 15a. The supply port 15b and the discharge port 15c are holes communicating with the storage space 15a. The supply port 15b and the discharge port 15c are formed with the storage space 15a interposed therebetween. The supply port 15b is fluidly connected to a liquid supply pipe 50. The discharge port 15c is fluidly connected to a liquid discharge pipe 52.

The film forming apparatus 1 further includes a liquid tank 90, the liquid supply pipe 50, the liquid discharge pipe 52, and a pump 80. As shown in FIG. 1, the liquid tank 90 contains the plating solution L. The liquid supply pipe 50 connects the liquid tank 90 and the housing 15. The liquid supply pipe 50 is provided with the pump 80. The pump 80 supplies the plating solution L from the liquid tank 90 to the housing 15. The liquid discharge pipe 52 connects the liquid tank 90 and the housing 15. The liquid discharge pipe 52 is provided with a pressure regulating valve 54. The pressure regulating valve 54 regulates the pressure (fluid pressure) of the plating solution L in the storage space 15a to a predetermined pressure.

In the present embodiment, by driving the pump 80, the plating solution L is sucked from the liquid tank 90 into the liquid supply pipe 50. The sucked plating solution L is pressure-fed from the supply port 15b to the storage space 15a. The plating solution L in the storage space 15a is returned to the liquid tank 90 via the discharge port 15c. In this way, the plating solution L circulates in the film forming apparatus 1.

Further, by continuing the driving of the pump 80, the fluid pressure of the plating solution L in the storage space 15a can be maintained at a predetermined pressure by the pressure regulating valve 54. The pump 80 is for pressing the electrolyte membrane 13 on which the fluid pressure of the plating solution L is acting against the masking material 60. The pump 80 is for increasing the fluid pressure of the plating solution L contained in the housing 15, and corresponds to a “booster mechanism” of the present disclosure. However, the booster mechanism is not particularly limited as long as the masking material 60 can be pressed by the electrolyte membrane 13. Instead of the pump 80, an injection mechanism composed of a piston and a cylinder for injecting the plating solution L may be used.

In one example, the mount base 40 is made of a conductive material (e.g., metal). The mount base 40 includes a recess 41. The recess 41 is a portion that is recessed relative to an opposite surface 40a of the mount base 40 to house the substrate B therein.

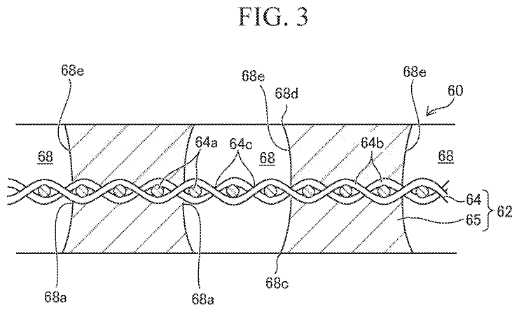

FIG. 2 is a schematic perspective view of the masking material 60 of the film forming apparatus 1 shown in FIG. 1, and a schematic perspective view of the substrate B on which the metal film F is formed. FIG. 3 is a cross-sectional view of a main portion of the masking material 60 being placed on the substrate B. The masking material 60 includes a frame 61 and a screen mask 62.

On the side of the frame 61 adjacent to the electrolyte membrane 13, the frame 61 supports a peripheral edge 62a of the screen mask 62. Specifically, the peripheral edge 62a of the screen mask 62 is securely attached to the frame 61. In the present embodiment, the screen mask 62 has a rectangular outer shape. Accordingly, the frame 61 has a rectangular frame-like shape. The material of the frame 61 is not particularly limited as long as the frame 61 can retain the shape of the masking material 60. Examples of the material of the frame 61 may include a metal material such as stainless steel, or a resin material such as a thermoplastic resin. The frame 61 is formed by punching a metallic plate, for example, and has a thickness of about 1 mm to 3 mm.

The screen mask 62 includes a penetrating portion 68 corresponding to the predetermined pattern P of the metal film F. The screen mask 62 includes a mesh portion 64 and a mask portion 65. The screen mask 62 is a flexible mask of about 50 μm to 400 μm in thickness. On the side of the frame 61 adjacent to the substrate B, the screen mask 62 is supported by the frame 61.

The mesh portion 64 is securely attached to the frame 61. The mesh portion 64 is stretched at a predetermined tension so as to cover the opening of the frame 61. The mesh portion 64 includes a plurality of openings 64c in a grid pattern. Specifically, as shown in FIG. 3 for example, the mesh portion 64 is a portion in which pluralities of oriented wires 64a, 64b are woven so as to cross each other into a mesh. The plurality of wires 64a are arranged at intervals, and the plurality of wires 64b intersecting the plurality of wires 64a are arranged at intervals. As a result, the mesh portion 64 includes the plurality of openings 64c in a grid pattern. The material of the wires 64a, 64b is not particularly limited as long as the wires 64a, 64b have corrosion resistance to the plating solution L. Examples of the material of the wires 64a, 64b may include metal materials such as stainless steel, and resin materials such as polyester.

The mask portion 65 is securely attached to the mesh portion 64. The mesh portion 64 is securely attached to the center of the mask portion 65 in a thickness direction. The mask portion 65 includes a penetrating portion 68 corresponding to the predetermined pattern P. The mask portion 65 is a portion that comes into close contact with the substrate B at the time of film formation by the pressure from the electrolyte membrane 13. The material of the mask portion 65 is not particularly limited as long as the mask portion 65 can be brought into close contact with the substrate B. Examples of the material of the mask portion 65 may include a resin material such as an acrylic resin, a vinyl acetate resin, a polyvinyl chloride resin, a polypropylene resin, a polyethylene resin, a polystyrene resin, a polycarbonate resin, a polyimide resin, an urethane resin, or a polyester resin, or a rubber material such as silicone rubber (PMDS) or ethylene propylene diene rubber (EPDM). The hardness of the rubber material may be HS100 or less, specifically HS50 or less, in Shore A hardness.

The mask portion 65 is made of an elastic material that may be compressed and elastically deform by the pressure from the electrolyte membrane 13. To ensure the adhesion to the substrate B, the amount of deformation in the thickness direction (pressing direction) of the mask portion 65 caused by the pressure from the electrolyte membrane 13 may be in the range of 5% to 20% with respect to the thickness of the mask portion before deformation. The screen mask 62 having the predetermined pattern P can be manufactured by a general silk screen manufacturing technique using an emulsion. Therefore, a detailed description of a method of manufacturing the screen mask 62 will be omitted.

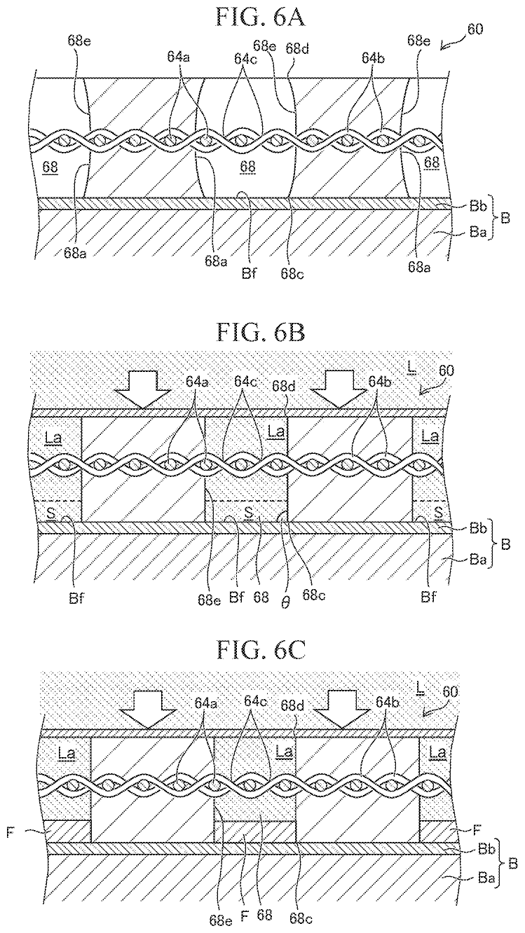

In the present embodiment, the mask portion 65 elastically deforms by a pressing force of the electrolyte membrane 13 as shown in FIG. 6B. The shape of the penetrating portion 68 before the deformation is formed such that, in the deformed state of the mask portion 65, the shape of the cross section of a formation space S of the penetrating portion 68 in which the metal film F is to be formed becomes rectangular. Such a shape of the penetrating portion 68 of the mask portion 65 may be obtained by analysis in advance, but may also be obtained, for example, by actually preparing a masking material and through an experiment. The formation space S is a space having a height from the surface of the substrate B corresponding to the thickness of the metal film F to be formed.

In the present embodiment, as shown in FIG. 3 and FIG. 6A, the penetrating portion 68 includes an expanded portion 68a that is expanded outwardly from a portion 68c contacting the substrate B toward electrolyte membrane 13 in the thickness direction of the mask portion 65. Note that the space other than the formation space S of the penetrating portion 68 is filled with an exudation solution La during film formation. More specifically, the expanded portion 68a of the penetrating portion 68 is a space formed to be expanded from the portion 68c contacting the substrate B and from a portion 68d contacting the electrolyte membrane 13 toward an interior of the mask portion 65 in the thickness direction of the mask portion 65. Herein, a side wall surface 68e forming the expanded portion 68c is a concave curved surface bent along the thickness direction.

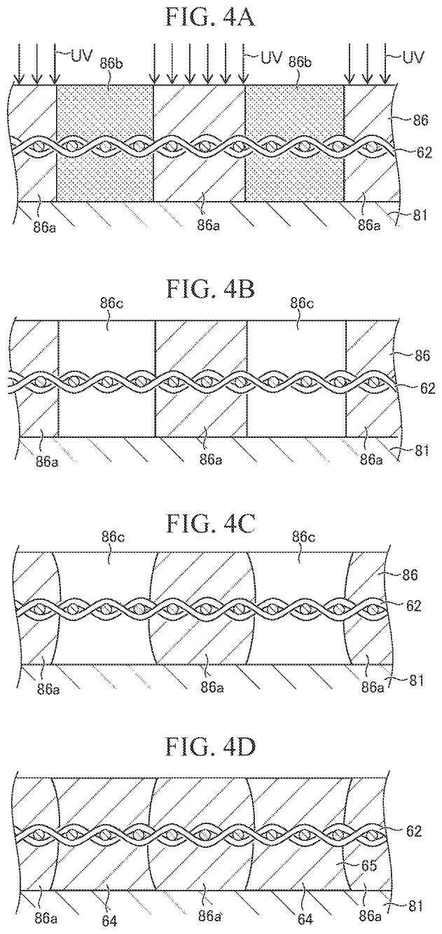

A method of manufacturing the above-described masking material 60 will be described. First, the frame 61 having the screen mask 62 securely attached thereto is prepared. Next, an uncured ultraviolet curable resin 86 is applied to the opposite surfaces of the screen mask 62 with a roller or a brush, and the screen mask 62 is placed on a resin plate 81 (see FIG. 4A). Next, the ultraviolet curable resin (emulsion) 86 is irradiated with ultraviolet light UV according to a predetermined pattern P to form a cured portion 86a according to the predetermined pattern. Next, an uncured portion 86b shown in FIG. 4A is rinsed to form a molding space 86c in which the mask portion 65 is to be molded as shown in FIG. 4B.

Next, as shown in FIG. 4C, the cured portion 86a is allowed to swell. At this time, when the resin of the cured portion 86a is a resin that swells with water, the cured portion 86a is allowed to swell by being exposed to water vapor or immersed in water. When the resin of the cured portion 86a is a resin that swells with an organic solvent, the cured portion 86a is allowed to swell by being immersed in the organic solvent. Accordingly, the molding space 86c that narrows toward the center in the thickness direction can be formed. Finally, as shown in FIG. 4D, a resin or a rubber as a material of the mask portion 65 is poured into this molding space 86c to mold the mask portion 65, and the cured portion 86a is removed by etching and also the resin plate 81 is eliminated from the mask portion 65. As a result, the masking material 60 having the mask portion 65 shown in FIG. 3 can be obtained.

Referring to FIG. 1, FIG. 5, and FIG. 6A to FIG. 6C, a film forming method using the film forming apparatus 1 will be described. First, as shown in FIG. 1 and FIG. 6A, a placing step is performed. In this step, as shown in FIG. 1, the substrate B is placed on the mount base 40. Specifically, the substrate B is housed in the recess 41 of the mount base 40. In the present embodiment, while the substrate B is housed in the recess 41, the surface of the substrate B protrudes from the opposite surface 40a (i.e., the surface facing the electrolyte membrane 13) of the mount base 40. This allows the mask portion 65 of the masking material 60 to be uniformly brought into contact with the surface of the substrate B. At this time, the alignment of the substrate B with respect to the anode 11 attached to the housing 15 may be adjusted, and the temperature of the substrate B may be adjusted.

Next, the masking material 60 is placed on the mount base 40. At this time, the masking material 60 is housed such that the surface of the substrate B is contained in an inner space 69 of the frame 61 of the masking material 60. As a result, as shown in FIG. 6A, the surface of the substrate B (i.e., the surface of the underlayer Bb) is covered with the mask portion 65 of the masking material 60.

Next, a pressing step shown in FIG. 5 and FIG. 6B is performed. In this step, the electrolyte membrane 13 is pressed against the substrate B via the screen mask 62 with the fluid pressure of the plating solution L contacting the electrolyte membrane 13. First, the linear actuator 70 is driven. Accordingly, the housing 15 is lowered toward the masking material 60 from the state of FIG. 1 to the state shown in FIG. 5. Note that when the masking material 60 is integrally attached to the housing 15 in a position facing the electrolyte membrane 13, the surface of the substrate B can be covered with the mask portion 65 of the masking material 60 by lowering the housing 15.

Next, the pump 80 is driven. As a result, the plating solution L is supplied to the storage space 15a of the housing 15. Since the pressure regulating valve 54 is provided in the liquid discharge pipe 52, the fluid pressure of the plating solution L in the storage space 15a is maintained at a predetermined pressure. Consequently, as shown in FIG. 5, the electrolyte membrane 13 deforms with a fluid pressure of the plating solution L toward the inner space 69 of the frame 61, and the screen mask 62 can be sandwiched between the electrolyte membrane 13 and the substrate B. Furthermore, the masking material 60 can be pressed by the electrolyte membrane 13 on which the fluid pressure of the plating solution L is acting.

As shown in FIG. 6B, such pressing allows the screen mask 62 to be brought into close contact with the surface of the substrate B. When the mask portion 65 is made of a rubber material, the mask portion 65 is compressed and elastically deforms with the fluid pressure of the plating solution L, thereby improving the adhesion between the mask portion 65 and the substrate B.

Specifically, by a pressing force of the electrolyte membrane 13 in the pressing step, the mask portion 65 elastically deforms such that the expansion of the expanded portion 68a of the penetrating portion 68 narrows. In a state where the mask portion 65 is elastically deformed, the shape of the cross section of the formation space S of the penetrating portion 68 in which the metal film F is to be formed becomes rectangular. In the present embodiment, the expanded portion 68a of the penetrating portion 68 is a space formed to be expanded from a portion 61c contacting the substrate B and from a portion 71d contacting the electrolyte membrane 13 toward an interior of the mask portion 65 in the thickness direction of the mask portion 65. Therefore, the shape of the penetrating portion 68 as a whole becomes substantially rectangular. In particular, since the side wall surface 68e forming the expanded portion 68a is a concave curved surface bent along the thickness direction, the penetrating portion 68 can be deformed into a more precise rectangular shape.

Furthermore, since the mask portion 65 is securely attached to the mesh portion 64, the mask portion 65 can be uniformly pressed via the mesh portion 64. This allows the mask portion 65 to elastically deform uniformly with the pressing force of the electrolyte membrane 13 and allows the shape of each penetrating portion 68 to be deformed into a stable rectangular shape.

In this way, as shown in FIG. 6B, the mask portion 65 deforms such that the side wall surface 68e forming the penetrating portion 68 substantially intersects a surface (film forming surface) Bf of the substrate B. In the present embodiment, an angle θ defined by the side wall surface 68e and the surface Bf may be in the range of 85° to 95°.

Further, when the pressing of the electrolyte membrane 13 is continued, as shown in FIG. 6B, the penetrating portion 68 formed in the screen mask 62 is filled with an exudation solution (plating solution) La exuded from the electrolyte membrane 13 swollen by the plating solution L.

Next, as shown in FIG. 5 and FIG. 6C, a film forming step is performed. In this step, a metal film F is formed while maintaining the pressing state by the electrolyte membrane 13 in the pressing step. Specifically, a voltage is applied between the anode 11 and the substrate B. This allows metal ions contained in the plating solution L to pass through the electrolyte membrane 13. The metal ions passed through the electrolyte membrane 13 move through the exudation solution La to the surface of the substrate B, and the metal ions are reduced at the surface of the substrate B.

Since the exudation solution La filled in the penetrating portion 68 is sealed inside the penetrating portion 68 by the electrolyte membrane 13, the metal film F having the predetermined pattern can be formed on the surface of the substrate B (see FIG. 2). The metal film F is a membrane derived from metal ions. Here, during film formation, the shape of the cross section of the formation space S of the penetrating portion 68 in which the metal film F is formed is rectangular. Therefore, it is possible to form the metal film F having a rectangular cross section as shown in FIG. 6C.

In particular, since the penetrating portion 68 is a space formed to be expanded from the side adjacent to the substrate B toward the electrolyte membrane 13, the shape of the cross section of the formation space S of the penetrating portion 68 in which the metal film F is to be formed tends to be deformed into a more precise rectangular shape.

Furthermore, since the exudation solution La is uniformly pressurized by the pressing of the electrolyte membrane 13, it is possible to form a homogeneous metal film F. After film formation, the housing 15 is raised by the linear actuator 70 such that the substrate B is separated from the electrolyte membrane 13 and the substrate B is taken from the mount base 40. In manufacturing a wiring using the metal film F, while leaving the portion on which the metal film F is formed, the conductive underlayer Bb formed on the surface of the insulating substrate Ba of the substrate B may be etched.

As described above, when the masking material 60 is integrally attached to the housing 15, the masking material 60 can support the weight of the plating solution L via the electrolyte membrane 13 when the housing 15 is raised by the linear actuator 70 to separate the substrate B from the electrolyte membrane 13. In this way, it is possible to avoid plastic deformation of the electrolyte membrane 13 due to the plating solution L under its own weight.

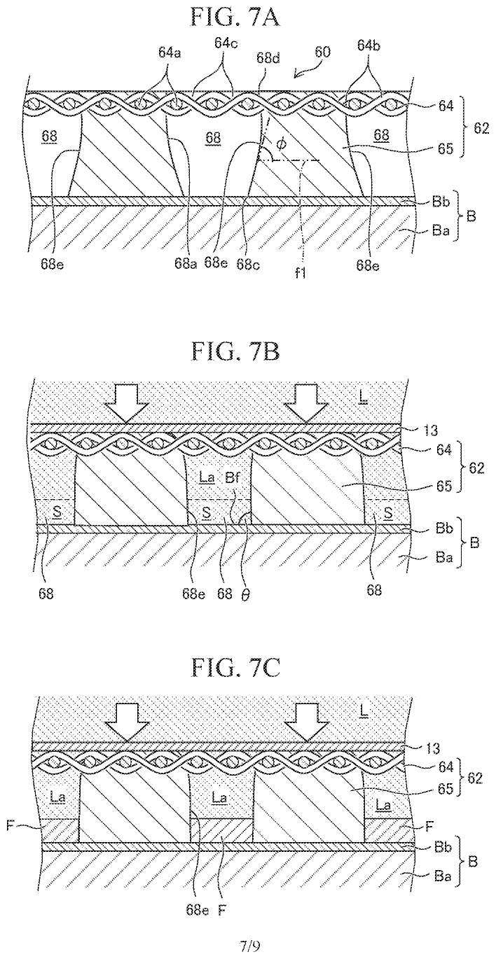

FIG. 7A is a schematic view for explaining a placing step using a masking material according to a second embodiment. FIG. 7B is a schematic view for explaining a pressing step thereof. FIG. 7C is a schematic view for explaining a film forming step thereof. The second embodiment differs from the first embodiment shown in FIG. 3 in the structure of the mask portion 65 of the masking material 60. Therefore, the following describes the difference from the foregoing embodiment, and a detailed description of a similar configuration will be omitted.

As shown in FIG. 7A, this masking material 60 also includes a mesh portion 64 having a plurality of openings 64c in a grid pattern. The mask portion 65 is securely attached to the mesh portion 64 at the surface of the mesh portion 64 on the side adjacent to the substrate B. Also in the present embodiment, the penetrating portion 68 includes an expanded portion 68a such that in a state where the mask portion 65 is elastically deformed, the shape of the cross section of the formation space S of the penetrating portion 68 in which the metal film F is to be formed becomes rectangular.

The expanded portion 68a is a space expanded outwardly from a portion 68c contacting the substrate B toward the electrolyte membrane 13 in the thickness direction of the mask portion 65. Specifically, the expanded portion 68a of the penetrating portion 68 is a space formed to be expanded from the portion 68c contacting the substrate B to the portion 68d contacting the electrolyte membrane 13 across the mask portion 65 in the thickness direction. Here, when the thickness of the metal film F to be formed is thin, the inclination angle ϕ of the side wall surface 68e forming the penetrating portion 68 may be fixed. In the present embodiment, with an assumption of the shape of this space, the inclination angle ϕ of the side wall surface 68e forming the penetrating portion 68 is greater at a position nearer to the electrolyte membrane 13 than to the substrate B (across the mask portion 65 in the thickness direction). Here, in the cross section, the inclination angle ϕ is an angle defined by an imaginary plane f1 that is in parallel with the surface of the screen mask 62 in an extended direction and the side wall surface 68e.

According to this example, as shown in FIG. 7B, when the electrolyte membrane 13 is pressed against the substrate via the masking material 60 with the fluid pressure of the plating solution L contacting the electrolyte membrane 13, its pressing force acts on the mask portion 65 via the mesh portion 64. Here, since the inclination angle ϕ of the side wall surface 68e is greater at a position nearer to the electrolyte membrane 13 than to the substrate B, the deformation of the mask portion 65 is greater at a position nearer to the electrolyte membrane 13 than to the substrate B. This can prevent the side wall surface 68e of the penetrating portion 68 from deforming while bulging. Consequently, the shape of the cross section of the formation space S of the penetrating portion 68 in which the metal film F is to be formed tends to be deformed into a more precise rectangular shape. After the pressing step, in the film forming step, it is possible to form the metal film F having a more precise rectangular cross section as shown in FIG. 7C.

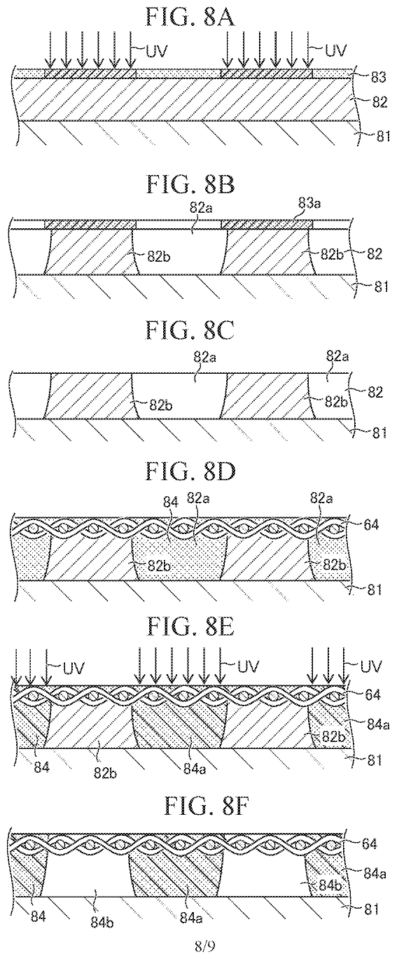

Referring to FIG. 8A to FIG. 8F, a method of manufacturing the above-described masking material 60 will be described. An uncured ultraviolet curable resin 83 is applied to the surface of a sheet material 82 made of copper placed on the surface of the resin plate 81 with a roller or a brush (see FIG. 8A). Next, the ultraviolet curable resin (emulsion) 83 is irradiated with ultraviolet light UV according to a predetermined pattern P to form a cured portion 83a according to the predetermined pattern. After that, the uncured ultraviolet curable resin is rinsed, and the copper of the sheet material 82 is etched using an acidic aqueous solution. This can form a gap 82a corresponding to the shape of the penetrating portion 68 as shown in FIG. 8B. Therefore, a remaining portion 82b of the sheet material 82 has a shape corresponding to the mask portion 65. After that, the cured portion 83a is removed from the remaining portion 82b of the sheet material 82 as shown in FIG. 8C.

Next, as shown in FIG. 8D, the gap of the sheet material 82 is filled with an uncured ultraviolet curable resin 84, and as shown in FIG. 8E, the filled uncured ultraviolet curable resin 84 is irradiated with ultraviolet light UV to form a cured portion 84a. After that, as shown in FIG. 8F, the copper of the remaining portion 82b is etched using an acidic aqueous solution. Finally, a resin or a rubber as a material of the mask portion 65 is poured into a molding space 84b from which the remaining portion 82b has been removed to mold the mask portion 65, and the cured portion 84a is removed by etching and also the resin plate 81 is eliminated from the mask portion 65. As a result, the masking material 60 having the mask portion 65 shown in FIG. 7A can be obtained.

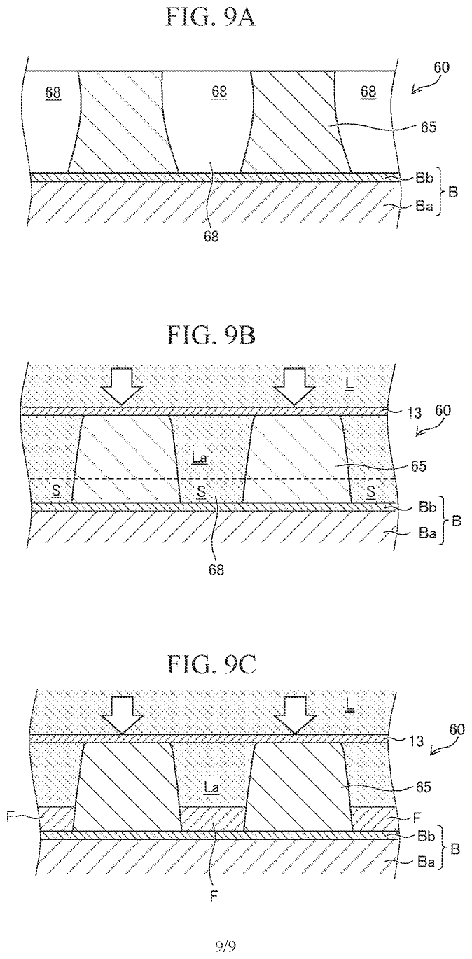

FIG. 9A is a schematic view for explaining a placing step using a masking material according to a third embodiment. FIG. 9B is a schematic view for explaining a pressing step thereof. FIG. 9C is a schematic view for explaining a film forming step thereof. The third embodiment differs from the second embodiment shown in FIG. 7A in that the masking material 60 does not include a mesh portion 64, and includes only a mask portion 65. Therefore, the following describes the difference from the foregoing embodiments, and a detailed description of a similar configuration will be omitted.

As shown in FIG. 9A, the masking material 60 includes only a mask portion 65 of the embodiment. Therefore, the masking material 60 tends to elastically deform in a compression direction. The mask portion 65 includes a penetrating portion 68. The penetrating portion 68 has a shape similar to that shown in FIG. 7A.

According to this example, as shown in FIG. 9B, when the electrolyte membrane 13 is pressed against the substrate B via the masking material 60 with the fluid pressure of the plating solution L contacting the electrolyte membrane 13, its pressing force directly acts on the masking material 60 (mask portion 65). As a result, the shape of the cross section of the formation space S of the penetrating portion 68 in which the metal film F is to be formed is deformed into a rectangular shape. Since the penetrating portion 68 is a space formed to be expanded from the side adjacent to the substrate B toward the electrolyte membrane 13, the shape of the cross section of the formation space S of the penetrating portion 68 in which the metal film F is to be formed is deformed into a precise rectangular shape. After the pressing step, in the film forming step, it is possible to form the metal film F having a precise rectangular cross section as shown in FIG. 9C.

Although the embodiments of the present disclosure have been described in detail above, the present disclosure is not limited to the above embodiments, and various design changes are possible in so far as they are within the spirit of the present disclosure in the scope of the claims.

What is claimed is:

1. A masking material for forming a metal film having a predetermined pattern on a surface of a substrate by electroplating in a state where the masking material is pressed by an electrolyte membrane,
wherein the masking material includes a penetrating portion according to the predetermined pattern,
wherein the masking material includes a mask portion and at least the mask portion contacting the substrate is made of an elastic material, and
wherein the penetrating portion includes an expanded portion that is expanded outwardly from a portion contacting the substrate toward the electrolyte membrane in a thickness direction of the mask portion such that in a state where the mask portion is elastically deformed by a pressing force of the electrolyte membrane, a shape of a cross section of a formation space of the penetrating portion in which the metal film is to be formed becomes rectangular.

2. The masking material according to claim 1, wherein the expanded portion of the penetrating portion is a space formed to be expanded from a portion contacting the substrate and from a portion contacting the electrolyte membrane toward an interior of the mask portion in the thickness direction of the mask portion.

3. The masking material according to claim 2, wherein a side wall surface forming the expanded portion is a concave curved surface bent along the thickness direction.

4. The masking material according to claim 1, wherein the expanded portion of the penetrating portion is a space formed to be expanded from a portion contacting the substrate to a portion contacting the electrolyte membrane across the mask portion in the thickness direction.

5. The masking material according to claim 1,
wherein the masking material includes a mesh portion including a plurality of openings in a grid pattern, and
wherein the mask portion is securely attached to the mesh portion.

6. A film forming apparatus for forming a metal film, provided with the masking material according to claim 1, the film forming apparatus comprising:
a housing having an opening at a position facing the substrate, the opening being covered with the electrolyte membrane while the housing contains a plating solution;
a moving mechanism configured to move at least one of the housing or the substrate to allow the electrolyte membrane and the substrate to be brought into contact with and separated from each other via the masking material;
a booster mechanism configured to increase a fluid pressure of the plating solution contained in the housing;
an anode disposed inside of the housing at a position facing the electrolyte membrane;
a power supply configured to apply a voltage between the anode and the substrate; and
the masking material placed between the electrolyte membrane and the substrate.

7. A film forming method for forming a metal film using the masking material according to claim 1, comprising:
covering a substrate with the masking material;
pressing an electrolyte membrane against the substrate via the masking material with a fluid pressure of a plating solution contacting the electrolyte membrane; and
applying a voltage between an anode contacting the plating solution and the substrate to allow metal ions contained in the plating solution to pass through the electrolyte membrane and form a metal film derived from the metal ions on the substrate in the predetermined pattern.
